(19) United States
(12) Patent Application Publication
(10) Pub. No.: US 2019/0062900 A1
(43) Pub. Date: Feb. 28, 2019

(54) OXIDE SINTERED BODY AND SPUTTERING TARGET

(71) Applicant: SUMITOMO METAL MINING CO., LTD., Tokyo (JP)

(72) Inventors: Tokuyuki NAKAYAMA, Ome-shi (JP); Eiichiro NISHIMURA, Ome-shi (JP); Fumihiko MATSUMURA, Ome-shi (JP)

(73) Assignee: SUMITOMO METAL MINING CO., LTD., Tokyo (JP)

(21) Appl. No.: 16/080,488

(22) PCT Filed: Jan. 31, 2017
(86) PCT No.: PCT/JP2017/003447

§ 371 Date: Aug. 28, 2018

(30) Foreign Application Priority Data
Feb. 29, 2016 (JP) 2016-037187

(51) Int. Cl. C23C 14/34; C04B 35/645; H01L 21/02

(52) U.S. Cl. CPC C23C 14/3414; H01L 21/02631; H01L 21/02565; C04B 35/645

(57) ABSTRACT

Provided is a sputtering target with which it is possible to manufacture an amorphous or crystalline oxide semiconductor thin film with an annealing treatment at a lower temperature than previously, said oxide semiconductor thin film comprising indium and gallium and having a high carrier mobility. Also provided is an oxide sintered body comprising indium and gallium, said oxide sintered body being optimal for obtaining said sputtering target. An oxide sintered body comprising oxides of indium and gallium, wherein the oxide sintered body is characterized by having a gallium content according to the atomic ratio Ga/(In+Ga) of 0.10 to 0.49, having a CIE 1976 color space L* value of 50 to 68, and being composed of an In₂O₃ phase with a bixbyite-type structure and, as a formation phase other than the In₂O₃ phase, a GaInO₃ phase with a β-Ga₂O₃-type structure, or a GaInO₃ phase with a β-Ga₂O₃-type structure and a (Ga, In)₂O₃ phase.

### TECHNICAL FIELD

The present invention relates to an oxide sintered body and a sputtering target, and more specifically, relates to a sputtering target which makes it possible to form an amorphous or crystalline oxide semiconductor thin film which is composed of indium and gallium and has a high carrier mobility even by an annealing treatment at a lower temperature as compared with the prior art and an oxide sintered body which is composed of indium and gallium and is optimal for obtaining the sputtering target.

### BACKGROUND ART

A thin film transistor (TFT) is one kind of field effect transistor (hereinafter referred to as FET). TFT is a three-terminal element equipped with a gate terminal, a source terminal, and a drain terminal as a basic configuration, and it is an active element which uses a semiconductor thin film formed on a substrate as a channel layer through which an electron or a hole moves and has a function of controlling the current flowing through the channel layer by applying a voltage to the gate terminal and switching the current between the source terminal and the drain terminal. TFT is currently an electronic device which has been the most widely put to practical use, and a representative application thereof is an element for liquid crystal driving.

Currently, the most widely used TFT is a metal-insulator-semiconductor-FET (MIS-FET) using a polycrystalline silicon film or an amorphous silicon film as a material for channel layer. MIS-FET using silicon cannot constitute a transparent circuit since it does not transmit visible light. For this reason, the device has a small aperture ratio of display pixels in the case of applying MIS-FET as a switching element for liquid crystal driving of a liquid crystal display.

In addition, recently a switching element for liquid crystal driving is also required to drive at a high speed as high definition of liquid crystal is required. In order to realize high speed driving, it is required to use a semiconductor thin film having a mobility of electrons or holes, which are a carrier, at least higher than that of amorphous silicon as the channel layer.

In order to cope with such a situation, Patent Document 1 proposes a transparent amorphous oxide thin film which is formed by a vapor phase film formation method and composed of elements In, Ga, Zn and O and exhibits semi-insulation properties and in which the composition of the oxide is InGaO₃(ZnO)ₘ (m is a natural number less than 6) as the composition when being crystallized and the carrier mobility (also referred to as the carrier electron mobility) exceeds 1 cm²V⁻¹·sec⁻¹ and the carrier concentration (also referred to as the carrier electron concentration) is 10¹⁶ cm⁻³ or less without addition of an impurity ion and a thin film transistor using this transparent semi-insulating amorphous oxide thin film as a channel layer.

However, the transparent amorphous oxide thin film (a-IGZO film) which is proposed in Patent Document 1, formed by a vapor phase film formation method such as a sputtering method or a pulsed laser vapor deposition method, and composed of elements In, Ga, Zn and O is pointed out to have a carrier mobility insufficient to cope with a more increase in the definition of display since the electron carrier mobility thereof is only briefly in a range of from 1 to 10 cm²V⁻¹sec⁻¹.

In addition, Patent Document 2 discloses a sputtering target intended to form the amorphous oxide thin film described in Patent Document 1, namely, a sintered body target containing at least In, Zn, and Ga, which contains In, Zn, and Ga as the composition and has a relative density of 75% or more and a resistance value ρ of 50 Ω·cm or less. However, the target of Patent Document 2 is a polycrystalline oxide sintered body having a homologous phase crystal structure and the amorphous oxide thin film obtained using this has a carrier mobility of only about 10 cm²V⁻¹sec⁻¹ in the same manner as in Patent Document 1.

In Patent Document 3, a thin film transistor using an oxide thin film in which gallium forms a solid solution in indium oxide, the atomic ratio Ga/(Ga+In) is from 0.001 to 0.12, the content of indium and gallium with respect to the entire metal atoms is 80 at % or more, and the oxide thin film has a bixbyite structure of In₂O₃ is proposed as a material for realizing a high carrier mobility and an oxide sintered body in which gallium forms a solid solution in indium oxide, the atomic ratio Ga/(Ga+In) is from 0.001 to 0.12, the content of indium and gallium with respect to the entire metal atoms is 80 at % or more, and the oxide sintered body has a bixbyite structure of In₂O₃ is proposed as a raw material therefor.

However, variation in properties of TFT due to crystal grain boundary is a problem in the case of applying a crystalline oxide semiconductor thin film as proposed in Patent Document 3 to TFT. In particular, it is extremely difficult to uniformly form TFT on a large glass substrate of the eighth generation or more.

Patent Document 4 proposes an oxide sintered body which contains indium and gallium as oxides and in which an In₂O₃ phase with a bixbyite-type structure is the main crystal phase, a GaInO₃ phase with a β-Ga₂O₃-type structure or the GaInO₃ phase and a (Ga, In)₂O₃ phase are finely dispersed in the In₂O₃ phase as crystal grains having an average grain size of 5 μm or less, and the content of gallium is 10 at % or more and less than 35 at % in terms of an atomic ratio Ga/(In+Ga).

However, the object of the oxide sintered body of Patent Document 4 is intended to provide a transparent conductive film which absorbs less blue light and has a low resistance, and it is not necessarily optimized as an oxide sintered body intended to form an amorphous oxide semiconductor thin film. For example, an annealing treatment in an oxidizing atmosphere at a high temperature of about 500° C. is required after sputtering film formation in the case of manufacturing an amorphous oxide semiconductor thin film containing indium and gallium as oxides using the oxide sintered body of Patent Document 4. Generally, the process temperature of TFT using amorphous silicon as the channel layer is about 350° C. or less, but there are problems such as a decrease in the yield of TFT due to the annealing treatment at a high temperature and an increase in the energy cost when an amorphous oxide semiconductor thin film containing indium and gallium as oxides is applied to this.

Patent Document 1: Japanese Unexamined Patent Application, Publication No. 2010-219538

Patent Document 2: Japanese Unexamined Patent Application, Publication No. 2007-073312

Patent Document 3: PCT International Publication No. WO2010/032422

Patent Document 4: PCT International Publication No. WO2009/008297

### DISCLOSURE OF THE INVENTION

### Problems to be Solved by the Invention

An object of the present invention is to provide a sputtering target which makes it possible to manufacture an amorphous or crystalline oxide semiconductor thin film which is composed of indium and gallium and has a high carrier mobility by an annealing treatment at a lower temperature as compared with the prior art and an oxide sintered body which is composed of indium and gallium and is optimal for obtaining the sputtering target.

### Means for Solving the Problems

The present inventors have newly found out that an amorphous or crystalline oxide semiconductor thin film which is composed of indium and gallium and has a high carrier mobility can be obtained by an annealing treatment at a lower temperature as compared with the prior art by the use of an oxide sintered body which contains indium and gallium and in which the content of gallium is 0.10 or more and 0.49 or less in terms of an atomic ratio Ga/(In+Ga) and the L* value in the CIE 1976 color space is 50 or more and 68 or less. In other words, the L* value in the CIE 1976 color space of the oxide sintered body of the present invention correlates with the carrier mobility of the oxide semiconductor thin film formed using the oxide sintered body. It has been found out that it is possible to manufacture an amorphous or crystalline oxide semiconductor thin film which is composed of indium and gallium and has a high carrier mobility even by an annealing treatment at a low temperature by controlling the L* value to be in the above range.

A first aspect of the present invention is an oxide sintered body containing oxides of indium and gallium, in which a content of gallium is 0.10 or more and 0.49 or less in terms of an atomic ratio Ga/(In+Ga), a L* value in CIE 1976 color space is 50 or more and 68 or less, and the oxide sintered body includes an In₂O₃ phase with a bixbyite-type structure and a GaInO₃ phase with a β-Ga₂O₃-type structure or a GaInO₃ phase with a β-Ga₂O₃-type structure and a (Ga, In)₂O₃ phase as a phase generated other than the In₂O₃ phase.

A second aspect of the present invention is the oxide sintered body according to the first aspect of the present invention, in which the content of gallium is 0.15 or more and 0.30 or less in terms of an atomic ratio Ga/(In+Ga).

A third aspect of the present invention is the oxide sintered body according to the first or second aspect of the present invention, in which the L* value in CIE 1976 color space is 58 or more and 65 or less.

A fourth aspect of the present invention is the oxide sintered body according to any one of the first to third aspects of the present invention, in which an X-ray diffraction peak intensity ratio of a GaInO₃ phase with a β-Ga₂O₃-type structure defined by the following Formula 1 is in a range of 24% or more and 85% or less.

100×I[GaInO₃ phase (111)]/{I[In₂O₃ phase (400)]+I[GaInO₃ phase (111)]}[%]. Formula 1

A fifth aspect of the present invention is a sputtering target obtained by processing the oxide sintered body according to any one of the first to fourth aspects of the present invention.

A sixth aspect of the present invention is a method of manufacturing an oxide sintered body, the method including mixing raw material powders containing an indium oxide powder and a gallium oxide powder and then sintering the powders mixed by an atmospheric sintering method to obtain an oxide sintered body, in which an average particle size of the raw material powders is set to 1.3 μm or less and a specific surface area value of the raw material powders is set to 10 m²/g or more and 17 m/g or less and the sintering by an atmospheric sintering method is conducted in an atmosphere containing oxygen at 1200° C. or more and 1550° C. or less for 10 hours or more and 30 hours or less.

### Effects of the Invention

In a case in which the oxide sintered body containing indium and gallium of the present invention, in which the content of gallium is 0.10 or more and 0.49 or less in terms of an atomic ratio Ga/(In+Ga) and the L* value in the CIE 1976 color space is 50 or more and 68 or less is used for example, as a sputtering target, an amorphous or crystalline oxide semiconductor thin film can be obtained by being formed by sputtering film formation and then subjected to a heat treatment. The amorphous or crystalline oxide semiconductor thin film formed has a low carrier concentration and a high carrier mobility by the effect that the oxide sintered body of the present invention contains gallium in a predetermined amount and the L* value is in a specific range, and it is possible to enhance the transporting properties of TFT when this is applied to TFT. Consequently, the oxide sintered body and the sputtering target of the present invention are industrially significantly useful.

### PREFERRED MODE FOR CARRYING OUT THE INVENTION

Hereinafter, the oxide sintered body, the sputtering target, and the oxide semiconductor thin film obtained using the oxide sintered body of the present invention will be described in detail.

### (1) Oxide Sintered Body

### (a) Composition

The oxide sintered body of the present invention is an oxide sintered body which is composed of indium and gallium and in which the content of gallium is 0.10 or more and 0.49 or less in terms of an atomic ratio Ga/(In+Ga) and a L* value in the CIE 1976 color space is 50 or more and 68 or less.

The content of gallium is 0.10 or more and 0.49 or less and more preferably 0.10 or more and 0.30 or less in terms of an atomic ratio Ga/(In+Ga). Gallium has an effect of increasing the crystallization temperature of the amorphous or crystalline oxide semiconductor thin film to be formed using the oxide sintered body of the present invention when the content of gallium is 0.10 or more and 0.49 or less in terms of an atomic ratio Ga/(In+Ga) to be the same as that in the oxide sintered body. In addition, gallium strongly bonds with oxygen and thus has an effect of decreasing the oxygen deficiency amount in the amorphous or crystalline oxide semiconductor thin film of the present invention. These effects are not sufficiently obtained in a case in which the content of gallium is less than 0.10 in terms of an atomic ratio Ga/(In+Ga). On the other hand, it is impossible to obtain a sufficiently high carrier mobility as an oxide semiconductor thin film in a case in which the content of gallium exceeds 0.49.

Incidentally, the oxide sintered body of the present invention substantially does not contain an element M which is an element in from positive monovalency to positive hexavalency other than indium and gallium. Here, the phrase “substantially does not contain an element M” means that each single M is contained at 500 ppm or less, preferably 200 ppm or less, and more preferably 100 ppm or less in terms of an atomic ratio M/(In+Ga+M). Specific examples of M may include Li, Na, K, Rb, and Cs as a positive monovalent element, Mg, Ni, Co, Cu, Ca, Sr, and Pb as a positive divalent element, Al, Y, Sc, B, and lanthanoids as a positive trivalent element, Sn, Ge, Ti, Si, Zr, Hf, C, and Ce as a positive tetravalent element, Nb and Ta as a positive pentavalent element, and W and Mo as a positive hexavalent element.

### (b) Color Difference

The L* value in the CIE 1976 color space of the oxide sintered body of the present invention is 50 or more and 68 or less and preferably 58 or more and 65 or less. The amorphous or crystalline oxide semiconductor thin film to be finally formed using the oxide sintered body composed of indium and gallium of the present invention has a high carrier mobility in a case in which the L* value is less than 50, and it is thus required to conduct an annealing treatment thereof at a higher temperature as compared with a case in which the L* value is in the above range. In contrast, the carrier mobility of the amorphous or crystalline oxide semiconductor thin film decreases in a case in which the L* value exceeds 68.

### (c) Structure of Sintered Body

It is preferable that the oxide sintered body of the present invention is configured to include an In₂O₃ phase with a bixbyite-type structure and a GaInO₃ phase with a β-Ga₂O₃-type structure. Here, it is preferable that gallium forms a solid solution in the In₂O₃ phase or constitutes the GaInO₃ phase. Gallium, which is a positive trivalent ion, basically substitutes the lattice position of indium, which is also a positive trivalent ion, in the case of forming a solid solution in the In₂O₃ phase. Basically, Ga occupies the original lattice position in the case of constituting the GaInO₃ phase but it may form a solid solution by slightly substituting the lattice position of In as a defect. In addition, it is not preferable that gallium hardly forms a solid solution in the In₂O₃ phase or the GaInO₃ phase with a β-Ga₂O₃-type structure and a (Ga, In)₂O₃ phase are less likely to be formed by the reasons that sintering does not proceed, and as a result, a Ga₂O₃ phase with a β-Ga₂O₃-type structure is formed. The Ga₂O₃ phase is poor in conductivity and thus causes abnormal discharge.

There is a case in which a (Ga, In)₂O₃ phase is generated in the oxide sintered body composed of indium and gallium as a phase other than these depending on the raw material powders and the sintering conditions, but it is preferable that the oxide sintered body of the present invention does not substantially include the (Ga, In)₂O₃ phase. In the present invention, an effect that the oxide semiconductor thin film obtained has a high carrier mobility is obtained as the oxide sintered body substantially does not contain the (Ga, In)₂O₃ phase. Incidentally, the phrase “substantially does not contain the (Ga, In)₂O₃ phase” means that the weight ratio of the (Ga, In)₂O₃ phase with respect to the entire phases constituting the oxide sintered body of the present invention determined by Rietveld analysis is, for example, 8% or less, preferably 5% or less, more preferably 3% or less, still more preferably 1% or less, and yet still more preferably 0%.

It is preferable that at least the crystal grains of the GaInO₃ phase has an average grain size of 5 μm or less between the In₂O₃ phase with a bixbyite-type structure and the GaInO₃ phase with a β-Ga₂O₃-type structure which constitute the oxide sintered body of the present invention. The crystal grains of the GaInO₃ phase are less likely to be sputtered as compared with the crystal grains of the In₂O₃ phase with a bixbyite-type structure, and thus nodules are generated and arcing is caused in some cases as the crystal grains of the GaInO₃ phase dig and remain. In other words, arcing can be prevented by controlling the average grain size of the crystal grains of the GaInO₃ phase to 5 μm or less.

### (2) Method of Manufacturing Oxide Sintered Body

In the manufacture of the oxide sintered body of the present invention, oxide powders composed of an indium oxide powder and a gallium oxide powder are used as raw material powders.

In the manufacturing process of the oxide sintered body of the present invention, these raw material powders are mixed together and then molded and the molded product is sintered by an atmospheric sintering method. The L* value in the CIE 1976 color space of the oxide sintered body of the present invention strongly depends on the manufacturing conditions in each step of such a manufacturing process of the oxide sintered body, for example, the BET value, particle size, and mixing conditions of the raw material powders and the sintering conditions.

The average particle sizes of the raw material powders which are composed of an indium oxide powder and a gallium oxide powder and used in the manufacture of the oxide sintered body of the present invention are each set to preferably 1.3 μm or less and more preferably 1.0 μm or less. By regulating the average particle size of the raw material powder to 1.3 μm or less, at least the crystal grains of the GaInO₃ phase with a β-Ga₂O₃-type structure are reliably controlled to 5 μm or less in the structure of the oxide sintered body of the present invention as described above. Furthermore, the crystal grain size is controlled to 3 μm or less by setting the average particle size to 1.0 μm or less. The indium oxide powder is a raw material for ITO (tin-doped indium oxide), and the development of fine indium oxide powder exhibiting excellent sinterability has been advanced along with the improvement of ITO. The indium oxide powder is continuously used as a raw material for ITO in a large amount and thus it is recently possible to obtain a raw material powder having an average particle size of 1.0 μm or less. However, in the case of a gallium oxide powder, the amount thereof used is still smaller than that of the indium oxide powder and it is thus difficult to obtain a raw material powder having an average particle size of 1.3 μm or less in some cases. It is preferable to grind the coarse gallium oxide powder until to have an average particle size of 1.3 μm or less in a case in which only a coarse gallium oxide powder can be obtained.

In addition, the specific surface area (BET) values of the indium oxide powder and gallium oxide powder, which are the raw material powders, are preferably in a range of 10 m²/g or more and 17 m²/g or less and more preferably in a range of 12 m²/g or more and 15 m²/g or less. Sufficient sinterability is not exhibited in a case in which the BET value of each of the powders is less than 10 m²/g. The reduction of the oxide sintered body does not sufficiently proceed even in an atmosphere containing oxygen to be described later in a case in which the sintering does not proceed. In that case, it is concerned that, for example, the L* value of the oxide sintered body exceeds 68 and the carrier mobility of the oxide semiconductor thin film formed decreases in a case in which the oxide sintered body is used as a sputtering target. On the other hand, the L* value of the oxide sintered body is less than 50 in a case in which the BET value exceeds 17 m²/g, and as a result, the carrier concentration of the oxide semiconductor thin film formed increases too high in some cases.

In the sintering step of the oxide sintered body of the present invention, it is preferable to apply an atmospheric sintering method. The atmospheric sintering method is a convenient and industrially advantageous method and is a preferred means from the viewpoint of low cost as well.

In the case of using the atmospheric sintering method, a molded body is first fabricated as described above. The raw material powders are placed in a resin pot and mixed with a binder (for example, PVA) and the like by using a wet ball mill or the like. The oxide sintered body of the present invention is configured to include an In₂O₃ phase with a bixbyite-type structure and a GaInO₃ phase with a β-Ga₂O₃-type structure, and it further includes a (Ga, In)₂O₃ phase in some cases, but it is preferable that crystal grains of these phases are controlled to have an average grain size of 5 μm or less and finely dispersed. In addition, it is preferable that generation of the (Ga, In)₂O₃ phase is suppressed as low as possible. In addition, it is required not to generate a Ga₂O₃ phase with a β-Ga₂O₃-type structure, which causes arcing, other than these phases. It is preferable to conduct the ball mill mixing for 18 hours or more in order to satisfy these requirements. At this time, a hard ZrO₂ ball may be used as the mixing ball. After mixing, the slurry is taken out, filtered, dried and granulated. Thereafter, the granulated product thus obtained is molded by applying a pressure of about 9.8 MPa (0.1 ton/cm²) to 294 MPa (3 ton/cm²) thereto by using a cold isostatic press to obtain a molded body.

In the sintering step by an atmospheric sintering method, it is preferable that an atmosphere in which oxygen exists is set and it is more preferable that the oxygen volume fraction in the atmosphere exceeds 20%. The oxide sintered body is further densified particularly as the oxygen volume fraction exceeds 20%. Sintering of the surface of the molded body first proceeds at the early stage of sintering by excess oxygen in the atmosphere. Subsequently, sintering of the interior of the molded body in a reduced state proceeds, and finally a highly dense oxide sintered body is obtained.

In the atmosphere in which oxygen does not exist, sintering of the surface of the molded body does not first proceed, and as a result, the densification of the sintered body does not proceed. When oxygen does not exist, indium oxide is decomposed particularly at about 900° C. to 1000° C. and metal indium is generated and it is thus difficult to obtain the intended oxide sintered body.

The temperature range for atmospheric sintering may be set to 1200° C. or more and 1550° C. or less, but it is more preferably 1460° C. or more and 1490° C. or less in an atmosphere in which oxygen gas is introduced into the air in the sintering furnace in a case in which the BET values of the raw material powders are controlled to be in the above range, namely, to 10 m²/g or more and 17 m²/g or less. The sintering time is preferably 10 hours or more and 30 hours or less and more preferably 15 hours or more and 25 hours or less.

The sintering reaction does not sufficiently proceed in a case in which the sintering temperature is less than 1200° C. On the other hand, when the sintering temperature exceeds 1550° C., densification hardly proceeds, the member of the sintering furnace reacts with the oxide sintered body, and the intended oxide sintered body is not obtained. It is preferable to set the sintering temperature to less than 1500° C. particularly in a case in which the content of gallium exceeds 0.15 in terms of an atomic ratio Ga/(In+Ga). In the temperature region of 1500° C. or more, there is a case in which the generation of the (Ga, In)₂O₃ phase is significant. It is preferable that the (Ga, In)₂O₃ phase is not generated as described above in a case in which the oxide sintered body of the present invention is used in the formation of an oxide semiconductor thin film.

It is preferable that the rate of temperature increase until to have the sintering temperature is set to be in a range of 0.2° C./min to 5° C./min in order to prevent cracking of the sintered body and to advance debinding. The temperature may be raised to the sintering temperature by combining different rates of temperature increase if necessary as long as the rate of temperature increase is in this range. In the temperature raising process, the molded body may be held at a specific temperature for a certain period of time for the purpose of advancing debinding and sintering. When cooling the sintered body after being sintered, it is preferable to stop oxygen introduction and to lower the temperature to 1000° C. at a rate of temperature decrease of 0.2° C./min to 5° C./min and particularly in a range of 0.2° C./min or more and 1° C./min or less.

### (3) Target

The target of the present invention is obtained by processing the oxide sintered body of the present invention to a predetermined size. In the case of using the oxide sintered body as a target, the target can be obtained by further polishing the surface of the oxide sintered body and bonding the oxide sintered body to a backing plate. The shape of target is preferably a flat plate shape, but it may be a cylindrical shape. In the case of using a cylindrical target, it is preferable to suppress the generation of particles by the rotation of target. In addition, the oxide sintered body can be processed into, for example, a cylindrical shape and thus formed into a tablet and the tablet can be used for film formation by a vapor deposition method or an ion plating method.

In the case of using the oxide sintered body as a sputtering target, the density of the oxide sintered body of the present invention is preferably 6.3 g/cm³ or more and more preferably 6.7 g/cm³ or more. The generation of nodules is caused at the time of mass production in a case in which the density is less than 6.3 g/cm³. In addition, in the case of using the oxide sintered body as a tablet for ion plating, the density of the oxide sintered body of the present invention is preferably less than 6.3 g/cm³ and more preferably 3.4 g/cm³ or more and 5.5 g/cm³ or less. In this case, the sintering temperature is preferably set to less than 1200° C. in some cases.

### (4) Oxide Semiconductor Thin Film and Method of Forming the Same

The oxide semiconductor thin film of the present invention is obtained by once forming an amorphous oxide thin film on a substrate by a sputtering method, for example, using a sputtering target to be obtained from the oxide sintered body of the present invention and then subjecting the amorphous oxide thin film to an annealing treatment.

The oxide thin film before being subjected to the annealing treatment easily converts into an amorphous film as the oxide sintered body of the present invention is basically configured to include an In₂O₃ phase with a bixbyite-type structure and a GaInO₃ phase with a β-Ga₂O₃-type structure. It is preferable since the amorphous oxide semiconductor thin film is easily wet-etched using a relatively weak acid-based etchant such as oxalic acid in the TFT manufacturing process.

It is important that the crystallization temperature of the amorphous oxide semiconductor thin film is high in order to exhibit favorable wet etching properties, but this crystallization temperature is related to the structure of oxide sintered body. In other words, in the case of including not only an In₂O₃ phase with a bixbyite-type structure but also a GaInO₃ phase with a β-Ga₂O₃-type structure as the oxide sintered body of the present invention, an oxide thin film, which is obtained using the oxide sintered body and has a content of gallium of 0.10 or more and 0.49 or less in terms of an atomic ratio Ga/(In+Ga), has a crystallization temperature of 230° C. or more, more preferably 300° C. or more, and still more preferably 350° C. or more and converts into a stable amorphous film. In contrast, in a case in which the oxide sintered body is configured to include only an In₂O₃ phase with a bixbyite-type structure, the oxide thin film obtained using this has a low crystallization temperature of approximately 200° C. and does not exhibit sufficient amorphous nature. In this case, microcrystals are already generated after the film formation, and amorphous and crystalline portions are intermingled with each other, and it is thus difficult to conduct patterning by wet etching by the generation of residue and the like.

The film forming step in the present invention is not particularly limited, but a general sputtering method is preferable. In particular, the direct current (DC) sputtering method is industrially advantageous since it is less affected by heat at the time of film formation and enables high speed film formation. It is preferable to use a mixed gas composed of an inert gas and oxygen, particularly argon and oxygen as a sputtering gas in order to form the oxide semiconductor thin film of the present invention by a direct current sputtering method. In addition, it is preferable to conduct sputtering by setting the internal pressure of the chamber of the sputtering apparatus to from 0.1 to 1 Pa, particularly from 0.2 to 0.8 Pa.

As the substrate, a glass substrate is representative, and alkali-free glass is preferable, but those that can withstand the process conditions described above can be used among resin plates and resin films.

In the film forming step, for example, after vacuum evacuation to 2×10⁻⁴ Pa or less, a mixed gas composed of argon and oxygen is introduced into the sputtering apparatus, the gas pressure is set to from 0.2 to 0.8 Pa, direct current plasma is generated by applying a direct current power so that the direct current power to the area of the target, namely, the direct current power density is in a range of about from 1 to 7 W/cm², and pre-sputtering can be conducted. After this pre-sputtering is conducted for from 5 to 30 minutes, it is preferable to correct the position of the substrate if necessary and then to conduct sputtering.

In the sputtering film formation in the film forming step described above, the direct current power to be applied is increased in order to increase the film forming rate.

The amorphous or crystalline oxide semiconductor thin film of the present invention is obtained by forming the amorphous oxide thin film described above and subjecting this to an annealing treatment. As one method until the annealing treatment, for example, an amorphous oxide thin film is once formed at a low temperature such as around room temperature, thereafter, an annealing treatment thereof is conducted at a temperature lower than the crystallization temperature to obtain an oxide semiconductor thin film which maintains the amorphous nature or an annealing treatment thereof is conducted at a temperature equal to or higher than the crystallization temperature to obtain a crystalline oxide semiconductor thin film. As another method, an amorphous oxide semiconductor thin film is formed by heating the substrate at a temperature lower than the crystallization temperature, preferably from 100° C. to 300° C. Subsequently to this, an annealing treatment thereof may be further conducted under the same conditions as the above to obtain an amorphous or crystalline oxide semiconductor thin film. The heating temperature in these two methods may be briefly 600° C. or less and can be set to be equal to or lower than the strain point of an alkali-free glass substrate.

As the annealing treatment conditions, a temperature lower than the crystallization temperature or equal to or higher than the crystallization temperature and an oxidizing atmosphere are preferably set. As the oxidizing atmosphere, an atmosphere containing oxygen, ozone, water vapor, nitrogen oxide or the like is preferable. As the annealing temperature, any temperature can be applied as long as it is from 200° C. to 600° C., but it is preferably a lower temperature of from 200° C. to 500° C. and more preferably from 200° C. to 350° C. as a semiconductor process. As the annealing time, the time to be kept at the annealing temperature is from 1 to 120 minutes and preferably from 5 to 60 minutes.

The composition of indium and gallium in the amorphous or crystalline oxide semiconductor thin film of the present invention is almost the same as the composition in the oxide sintered body of the present invention. The content of gallium is preferably 0.10 or more and 0.49 or less and more preferably 0.10 or more and 0.30 or less in terms of an atomic ratio Ga/(In+Ga).

The amorphous or crystalline oxide semiconductor thin film of the present invention has a carrier concentration decreased to 3.0×10¹⁸ cm⁻³ or less and a carrier mobility of 10 cm²V⁻¹sec⁻¹ or more by being formed using an oxide sintered body having the composition and structure controlled as described above as a sputtering target or the like and subjected to an annealing treatment under the appropriate conditions described above. More preferably, a carrier mobility of 15 cm²V⁻¹sec⁻¹ or more is obtained and particularly preferably a carrier mobility of 20 cm²V⁻¹sec⁻¹ or more is obtained.

The amorphous or crystalline oxide semiconductor thin film of the present invention is subjected to microfabrication required for an application such as TFT by wet etching or dry etching. Commonly, an appropriate substrate temperature can be selected from temperatures lower than the crystallization temperature, for example, from a range of from room temperature to 300° C. and an amorphous oxide thin film can be once formed and then subjected to microfabrication by wet etching. As the etchant, a weak acid can be generally used but a weak acid containing oxalic acid or hydrochloric acid as a main component is preferable. For example, a commercially available product such as ITO-06N manufactured by KANTO CHEMICAL CO., INC. can be used. Dry etching may be selected depending on the configuration of TFT.

The film thickness of the amorphous or crystalline oxide semiconductor thin film of the present invention is not limited, but is from 10 to 500 nm, preferably from 20 to 300 nm, and more preferably from 30 to 100 nm. Sufficient semiconductor properties are not obtained, and as a result, a high carrier mobility is not realized when the film thickness is less than 10 nm. On the other hand, it is not preferable that the film thickness exceeds 500 nm since a problem arises in productivity.

### EXAMPLES

Hereinafter, the present invention will be described in more detail with reference to Examples, but the present invention is not limited by these Examples.

### <Evaluation of Oxide Sintered Body>

The composition of the metal elements in the oxide sintered body obtained was examined by ICP atomic emission spectroscopy. The density of the sintered body was measured by the Archimedes' method. The identification of phases generated was conducted by a powder method using an X-ray diffractometer (manufactured by Koninklijke Phillips N.V.). The L* value in the CIE 1976 color space of the oxide sintered body was measured by using a spectrophotometer (manufactured by BYK-Gardner GmbH).

### <Evaluation on Basic Properties of Oxide Thin Film>

The composition of the oxide thin film obtained was examined by ICP atomic emission spectroscopy. The film thickness of the oxide thin film was measured by using a surface roughness tester (manufactured by KLA-Tencor Corporation). The film forming rate was calculated from the film thickness and the film forming time. The carrier concentration and mobility of the oxide thin film were determined by using a Hall effect measuring apparatus (manufactured by TOYO Corporation). The phases generated in the film were identified by X-ray diffraction measurement.

### Examples 1 to 10

An indium oxide powder and a gallium oxide powder were adjusted so as to have an average particle size of 1.0 μm or less and used as raw material powders. The specific surface area (BET) value of the indium oxide powder was 13.2 m²/g, and the BET value of the gallium oxide powder was 12.4 m²/g. As presented in Examples 1 to 10 in Table 1, these raw material powders were blended as to have an atomic ratio Ga/(In+Ga) of 0.10 or more and 0.49 or less, placed in a resin pot together with water, and mixed with water by using a wet ball mill. At this time, hard ZrO₂ balls were used and the mixing time was set to 18 hours. After mixing, the slurry was taken out, filtered, dried and granulated. The granulated product was molded by applying a pressure of 294 MPa thereto by using a cold isostatic press.

Next, the molded body was sintered as follows. The molded body was sintered at a sintering temperature of 1460° C. to 1490° C. for 20 hours in an atmosphere in which oxygen was introduced into the air in the sintering furnace at a proportion of 5 L/min per 0.1 m³ of furnace volume. At this time, the temperature was raised at 1° C./min, and oxygen introduction was stopped and the temperature was lowered to 1000° C. at 1° C./min when cooling the sintered body after being sintered.

Next, various properties of the oxide sintered body thus obtained were examined. The results are presented in Table 1. First, the composition analysis was conducted by ICP atomic emission spectroscopy, and it has been confirmed in all Examples that the composition of metal elements was almost the same as the charged composition at the time of blending of the raw material powders. Subsequently, the density of sintered body was measured by the Archimedes' method. Next, the phase identification of oxide sintered body was conducted by X-ray diffraction measurement. Incidentally, the X-ray diffraction peak intensity ratio of a GaInO₃ phase with a β-Ga₂O₃-type structure defined by the following Formula 1 is presented in Table 1 and Table 2 in the case of including a GaInO₃ phase with a β-Ga₂O₃-type structure.

100×I[GaInO₃ phase (111)]/{I[In₂O₃ phase (400)]+I[GaInO₃ phase (111)]}[%]. Formula 1

TABLE 1

| | | Specific surface area | | | | | |
|---|---|---|---|---|---|---|---|
| | | (BET) value | | | Sintered | Oxide | GaInO₃(111) |
| | Ga/(In + Ga) | (cm²/g) | | Sintering | body | sintered | Peak |
| | Atomic | Indium oxide | Gallium oxide | temperature | density | body | intensity |
| | ratio | powder | powder | (° C.) | (g/cm³) | L* | ratio |
| Example 1 | 0.10 | 13.2 | 12.4 | 1490 | 7.02 | 50 | 7 |
| Example 2 | 0.12 | 13.2 | 12.4 | 1490 | 7.00 | 54 | 16 |
| Example 3 | 0.15 | 13.2 | 12.4 | 1490 | 6.96 | 58 | 22 |
| Example 4 | 0.20 | 13.2 | 12.4 | 1460 | 6.88 | 60 | 33 |
| Example 5 | 0.25 | 13.2 | 12.4 | 1460 | 6.82 | 62 | 42 |
| Example 6 | 0.30 | 13.2 | 12.4 | 1460 | 6.76 | 65 | 54 |
| Example 7 | 0.35 | 13.2 | 12.4 | 1460 | 6.69 | 66 | 60 |
| Example 8 | 0.40 | 13.2 | 12.4 | 1460 | 6.58 | 68 | 71 |
| Example 9 | 0.45 | 13.2 | 12.4 | 1460 | 6.50 | 63 | 77 |
| Example 10 | 0.49 | 13.2 | 12.4 | 1460 | 6.43 | 57 | 81 |
| Comparative | 0.015 | 13.2 | 12.4 | 1490 | 6.71 | 83 | GaInO₃ |
| Example 1 | | | | | | | phase not |
| | | | | | | | generated |
| Comparative | 0.08 | 5.7 | 6.2 | 1490 | 6.60 | 71 | GaInO₃ |
| Example 2 | | | | | | | phase not |
| | | | | | | | generated |
| Comparative | 0.15 | 18.2 | 17.6 | 1490 | 6.99 | 48 | 17 |
| Example 3 | | | | | | | |
| Comparative | 0.30 | 18.2 | 17.6 | 1460 | 6.79 | 46 | 48 |
| Example 4 | | | | | | | |
| Comparative | 0.60 | 13.2 | 12.4 | 1460 | 6.20 | 75 | In₂O₃ |
| Example 5 | | | | | | | phase not |
| | | | | | | | generated |

### Comparative Example 1

An oxide sintered body was fabricated by the same method as in Examples 1 to 10 except that an indium oxide powder and a gallium oxide powder as raw material powders were blended so as to have an atomic ratio Ga/(In+Ga) of 0.015 as presented in Table 1. The various properties are presented in Table 1.

### Comparative Example 2

An oxide sintered body was fabricated by the same method as in Examples 1 to 10 except that the specific surface area (BET) value of the indium oxide powder of a raw material powder was 5.7 m²/g, the BET value of the gallium oxide powder of a raw material powder was 6.2 m²/g, and the indium oxide powder and the gallium oxide powder were blended so as to have an atomic ratio Ga/(In+Ga) of 0.08 as presented in Table 1. The various properties are presented in Table 1.

### Comparative Examples 3, 4

Oxide sintered bodies were fabricated by the same method as in Examples 3 and 6 except that the specific surface area (BET) value of the indium oxide powder of a raw material powder was 18.2 m²/g and the BET value of the gallium oxide powder of a raw material powder was 17.6 m²/g. The various properties are presented in Table 1.

### Comparative Example 5

An oxide sintered body was fabricated by the same method as in Examples 1 to 10 except that an indium oxide powder and a gallium oxide powder as raw material powders were blended so as to have an atomic ratio Ga/(In+Ga) of 0.60 as presented in Table 1. The various properties are presented in Table 1.

### Example 11

The oxide sintered body of Example 6 was processed into a size of 152 mm in diameter and 5 mm in thickness, and the sputtering surface was polished by using a cup grindstone so that the maximum height Rz was 3.0 μm or less. The oxide sintered body processed was bonded to a backing plate made of oxygen-free copper using metal indium, thereby obtaining a sputtering target.

Film formation by direct current sputtering was conducted at a substrate temperature of 200° C. using the sputtering target thus obtained and an alkali-free glass substrate (Corning Eagle XG). The sputtering target was attached to the cathode of a direct current magnetron sputtering apparatus (manufactured by Canon Tokki Corporation) equipped with a direct current power supply without having an arcing suppression function. At this time, the distance between the target and the substrate (holder) was fixed at 60 mm. After vacuum evacuation to 2×10⁻⁴ Pa or less, a mixed gas composed of argon and oxygen was introduced into the sputtering apparatus so as to have an appropriate oxygen ratio according to the amount of gallium in the target, and the gas pressure was adjusted to 0.6 Pa. A direct current plasma was generated by applying a direct current power of 300 W (1.64 W/cm²). After pre-sputtering for 10 minutes, the substrate was disposed right on the sputtering target, namely, at the stationary facing position, thereby once forming an oxide thin film having a film thickness of 50 nm. It has been confirmed that the composition of the oxide thin film thus obtained was almost the same as that of the target.

Subsequently, the oxide thin film once formed was subjected to a rapid thermal annealing (RTA) treatment, thereby obtaining an intended oxide semiconductor thin film. As the RTA treatment conditions, the oxide thin film was held in oxygen at 350° C. for 30 minutes as presented in Table 2. The crystallinity of the oxide semiconductor thin film after being subjected to the heat treatment was examined by X-ray diffraction measurement, and as a result, the amorphous nature thereof was maintained. The Hall effect of the amorphous oxide semiconductor thin film thus obtained was measured, and the carrier concentration and carrier mobility thereof were determined. The evaluation results obtained are presented in Table 2.

TABLE 2

| | Oxide | | Oxide semiconductor thin film | | | | |
|---|---|---|---|---|---|---|---|
| | sintered body | | | RTA | | | |
| | Ga/(In + Ga) | | Substrate | treatment | Crystallinity | Carrier | Carrier |
| | Atomic | | temperature | temperature | after RTA | concentration | mobility |
| | ratio | L* | (° C.) | (° C.) | treatment | (×10¹⁷ cm⁻³) | (cm²V⁻¹sec⁻¹) |
| Example 11 | 0.30 | 65 | 200 | 350 | Amorphous | 17 | 23.7 |
| Example 12 | 0.15 | 58 | 150 | 350 | Crystalline | 2.4 | 17.7 |
| Comparative | 0.30 | 46 | 200 | 500 | Amorphous | 15 | 23.5 |
| Example 6 | | | | | | | |
| Comparative | 0.15 | 48 | 150 | 400 | Crystalline | 2.6 | 18.1 |
| Example 7 | | | | | | | |
| Comparative | 0.015 | 83 | 25 | 300 | Crystalline | 88 | 16.5 |
| Example 8 | | | | | | | |
| Comparative | 0.60 | 75 | 200 | 350 | Amorphous | 0.043 | 6.8 |
| Example 9 | | | | | | | |

### Comparative Example 6

An amorphous oxide semiconductor thin film was fabricated by the same method as in Example 11 except that the oxide sintered body of Comparative Example 4 was used as a sputtering target and only the temperature was changed to 500° C. among the RTA treatment conditions.

### Example 12

A sputtering target was fabricated by the same method as in Example 11 except that the oxide sintered body of Example 3 was used and the substrate temperature at the time of film formation was set to 150° C., and an oxide thin film having a thickness of 50 nm was once formed.

Subsequently, the oxide thin film once formed was subjected to a RTA treatment, thereby obtaining an intended oxide semiconductor thin film. Only the temperature was changed to 350° C. among the RTA treatment conditions. The crystallinity of the oxide semiconductor thin film after being subjected to the heat treatment was examined by X-ray diffraction measurement, and as a result, it has been revealed that the oxide semiconductor thin film has been crystallized. The Hall effect of the crystalline oxide semiconductor thin film thus obtained was measured, and the carrier concentration and carrier mobility thereof were determined. The evaluation results obtained are presented in Table 2.

### Comparative Example 7

A crystalline oxide semiconductor thin film was fabricated by the same method as in Example 12 except that the oxide sintered body of Comparative Example 3 was used as a sputtering target and only the temperature was changed to 400° C. among the RTA treatment conditions.

### Comparative Example 8

A crystalline oxide semiconductor thin film was fabricated by the same method as in Example 11 except that the oxide sintered body of Comparative Example 1 was used as a sputtering target, the substrate temperature at the time of film formation was set to 25° C. (room temperature), and only the temperature was changed to 300° C. among the RTA treatment conditions.

### Comparative Example 9

An amorphous oxide semiconductor thin film was fabricated by the same method as in Example 11 except that the oxide sintered body of Comparative Example 5 was used as a sputtering target.

### [Evaluation]

From Table 1, it can be seen in Examples 1 to 10 that the L* value in the CIE 1976 color space of the oxide sintered bodies fabricated using the raw material powders is in a range of 50 or more and 68 or less as the specific surface area (BET) values of the indium oxide powder and gallium oxide powder, which are the raw material powders, are controlled to 13.2 m²/g and 12.4 m²/g in the range of 10 to 17 m²/g in a case in which the gallium content is 0.10 or more and 0.49 or less in terms of an atomic ratio Ga/(In+Ga). The L* value is in a range of 58 or more and 65 or less particularly in a case in which the gallium content is 0.15 or more and 0.30 or less in terms of an atomic ratio Ga/(In+Ga). Furthermore, the sintered body density of the oxide sintered bodies of Examples 1 to 10 satisfied 6.3 g/cm³ or more and it was 6.7 g/cm³ or more when the gallium content was 0.15 or more and 0.30 or less in terms of an atomic ratio Ga/(In+Ga). In addition, the oxide sintered bodies of Examples 1 to 10 were substantially configured to include an In₂O₃ phase with a bixbyite-type structure and a GaInO₃ phase with a β-Ga₂O₃-type structure.

In contrast, in Comparative Examples 1 and 2, the gallium content in the oxide sintered bodies is lower than the range of the present invention. In Comparative Example 1, an oxide sintered body configured to include only an In₂O₃ phase with a bixbyite-type structure is formed for this reason. In addition, in Comparative Example 5, an In₂O₃ phase is not generated since the gallium content is too high. In other words, in Comparative Examples 1, 2 and 5, the intended oxide sintered body of the present invention is not obtained even when the average particle sizes and BET values of the raw material powders are controlled. Furthermore, the L* value in the CIE 1976 color space of the oxide sintered bodies of Comparative Examples 1, 2 and 5 does not satisfy the range of 50 or more and 68 or less.

Next, the carrier properties of amorphous and crystalline oxide semiconductor thin films composed of indium and gallium are presented in Table 2.

It can be seen that the oxide semiconductor thin film of Example 11 is amorphous and satisfies a carrier mobility of 10 cm²V⁻¹sec⁻¹ or more. In the oxide semiconductor thin film of Example 11, oxygen deficiency disappears by a RTA treatment conducted under the conditions of the air and 350° C. and a carrier concentration of 3.0×10¹⁸ cm⁻³ or less is satisfied, that is, 1.7×10¹⁸ cm⁻³ is obtained. In contrast, in Comparative Example 6, a carrier concentration and a mobility equivalent to those in Example 11 are eventually obtained by increasing the RTA treatment temperature to 500° C. since an oxide sintered body in which the L* value in the CIE 1976 color space does not satisfy the range of the present invention is used as a sputtering target. In other words, it has been demonstrated that it is possible to conduct a low temperature treatment as the L* value of the oxide sintered body satisfies the range of 50 or more and 68 or less of the present invention.

In the comparison between Example 12 and Comparative Example 7 as well, it is apparent that it is possible to conduct a low temperature treatment as the L* value in the CIE 1976 color space of the oxide sintered body satisfies the range of 50 or more and 68 or less of the present invention although there is a difference that the oxide semiconductor thin film is a crystalline oxide semiconductor thin film.

In addition, it can be seen that the carrier concentration exceeds 3.0×10¹⁷ cm⁻³ in a case in which the gallium content is less than 0.10 in terms of an atomic ratio Ga/(In+Ga) in Comparative Example 8. On the other hand, the carrier mobility is only less than 10 cm²V⁻¹sec⁻¹ in a case in which the atomic ratio exceeds 0.49.

1: An oxide sintered body comprising oxides of indium and gallium, wherein
a content of gallium is 0.10 or more and 0.49 or less in terms of an atomic ratio Ga/(In+Ga),
a L* value in CIE 1976 color space is 50 or more and 68 or less, and
the oxide sintered body includes an In₂O₃ phase with a bixbyite-type structure and a GaInO₃ phase with a β-Ga₂O₃-type structure or a GaInO₃ phase with a β-Ga₂O₃-type structure and a (Ga, In)₂O₃ phase as a phase generated other than the In₂O₃ phase.

2: The oxide sintered body according to claim 1, wherein a content of gallium is 0.15 or more and 0.30 or less in terms of an atomic ratio Ga/(In+Ga).

3: The oxide sintered body according to claim 1, wherein the L* value in CIE 1976 color space is 58 or more and 65 or less.

4: The oxide sintered body according to claim 1, wherein an X-ray diffraction peak intensity ratio of a GaInO₃ phase with a β-Ga₂O₃-type structure defined by the following Formula 1 is in a range of 24% or more and 85% or less.
100×I[GaInO₃ phase (111)]/{I[In₂O₃ phase (400)]+I[GaInO₃ phase (111)]}) [%]. Formula 1

5: A sputtering target obtained by processing the oxide sintered body according to claim 1.

6: A method of manufacturing an oxide sintered body, the method comprising:
Mixing raw material powders containing an indium oxide powder and a gallium oxide powder, and then
sintering the powders mixed by an atmospheric sintering method to obtain an oxide sintered body, wherein
an average particle size of the raw material powders is set to 1.3 μm or less and a specific surface area value of the raw material powders is set to 10 m²/g or more and 17 m²/g or less, and
the sintering by an atmospheric sintering method is conducted in an atmosphere containing oxygen at 1200° C. or more and 1550° C. or less for 10 hours or more and 30 hours or less.
